(19) United States
(12) Patent Application Publication
(10) Pub. No.: US 2022/0263488 A1
(43) Pub. Date: Aug. 18, 2022

(54) BAW RESONATOR WITH REDUCED LATERAL MODES

(71) Applicant: RF360 EUROPE GMBH, Munchen (DE)

(72) Inventors: Florian LOCHNER, Taufkirchen (DE); Erik MUELLER, München (DE)

(21) Appl. No.: 17/597,472

(22) PCT Filed: Jul. 24, 2020
(86) PCT No.: PCT/EP2020/070950

§ 371 Date: Jan. 6, 2022

(30) Foreign Application Priority Data
Jul. 30, 2019 (DE) 10 2019 120 558.1

(51) Int. Cl. H03H 9/02

(52) U.S. Cl. CPC H03H 9/02157

(57) ABSTRACT

A BAW resonator (RN) with reduced lateral modes is provided. The resonator has an active stack of bottom electrode (BE), piezoelectric material (PM) and top electrode (TE) and at least one element of this active stack has a curved side wall (CSW). Two or more curved side walls may be arranged on spheres, on cylinders or prisms with an elliptical footprint with different radii.

The present invention refers to BAW resonators (BAW=bulk acoustic wave) with reduced lateral modes and to corresponding RF filters and multiplexers.

In wireless communication devices RF filters are used to separate wanted RF signals from unwanted RF signals. Such RF filters can work with electro acoustic resonators such as BAW resonators. In BAW resonators a piezoelectric material is arranged between a bottom electrode layer and a top electrode layer. Due to the piezoelectric effect—when an RF signal is applied to the electrodes—an acoustic wave, specifically a longitudinal wave—can propagate in the vertical direction.

However, other wave modes may also be excited and deteriorate the acoustic and electric performance of the resonator and of the filter comprising the resonator. Such unwanted modes can be lateral modes that have a wave vector that has a horizontal component.

From U.S. Pat. No. 6,150,703 BAW resonators are known. The resonators have non-parallel side walls that should reduce the intensity of lateral modes.

However, it is desired to have RF filters and corresponding resonators with a further improved performance.

Specifically, it is desired to have resonators with an increased spectral purity, an increased quality factor Q, with further reduced lateral modes and filters with a reduced insertion loss and reduced irregularities and a smoother transfer function.

To that end, a BAW resonator with reduced lateral modes is provided. The BAW resonator comprises an active stack. The active stack includes a bottom electrode in a bottom electrode layer, a top electrode in a top electrode layer and a piezoelectric material in a piezoelectric layer. The piezoelectric material in the piezoelectric layer is arranged between the bottom electrode layer and the top electrode layer. At least one element selected from the active stack has a curved side wall.

The curved side wall of the element of the active stack leaves the wanted acoustic mode propagating in the vertical direction essentially unchanged while reducing the negative effects of unwanted lateral modes. Specifically, the curved side wall can act as a deflection element for horizontal wave vector components such that a constructive interference is reduced or even eliminated.

The BAW resonator can be a resonator of the SMR-type (SMR=solidly mounted resonator) with an acoustic mirror arranged below the bottom electrode. However, It is also possible that the resonator is of an FBAR-type (FBAR=film bulk acoustic resonator) where a cavity is arranged below the bottom electrode layer. The acoustic mirror in the case of an SMR-type resonator and the cavity in the case of an FBAR-type resonator have the effect that the resonator structure is acoustically decoupled from its environment such that a dissipation of acoustic energy is reduced.

The term “side wall” of an element of the active stack denotes the essentially horizontal areas or surfaces of the stacked construction, specifically of the bottom electrode layer, the piezoelectric material and the top electrode layer.

The height of the corresponding side walls essentially equals the thickness of the corresponding layer. A corresponding element of the active stack can have corners and edges between the corners. The corresponding side walls denote the vertical surfaces between the corresponding edges.

It is possible that two or all side walls of the active stack have a curved side wall.

Thus, the number of curved side walls is not limited to one. It is possible that each of the elements, e.g. the bottom electrode, the top electrode and the piezoelectric material in between has a curved side wall. It is also possible that each of these elements has two or more curved side walls. Specifically, it is possible that each side wall of each element of the active stack is curved.

It is possible that the number of side walls of one or more elements of the active stack is an odd number.

The use of odd numbers for the numbers of side walls essentially prevents that each side wall has a specifically associated opposite side wall such that a constructive interference of lateral modes caused by iterative reflection between the associated side walls is prevented.

Correspondingly, it is possible that the number of side walls per element of the active stack is 3, 4, 5, 6, 7, 8, 9, 10 11 or a higher number but it is preferred that the number of side walls of the corresponding elements is 3, 5, 7, 9, 11 or a higher odd number.

It is possible that one or more curved side walls are arranged on a sphere, on a cylinder or on a prism.

Thus, the surface of the corresponding side wall is arranged on the respective geometric shape and establishes a segment of the geometric shape. In this respect, a prism is a three-dimensional shape that has two parallel areas of the same size and of the same shape. Thus, a cylinder is a special embodiment of a prism.

The parallel areas of the prism establish the bottom and the top of the prism. The bottom and the top of the prism can be circles, ellipses or other shapes of a reduced order of symmetry.

It is possible that two or more curved side walls are arranged on spheres, on cylinders or prisms with an elliptical footprint with different radii.

The use of different radii for different curved side walls enhances the deflection effect, resulting in a further reduced contribution of lateral modes to the acoustics of the resonator.

Radii corresponding to curved side walls can be in the range between 0.1 d and 10d where d is the square root of the base area of the resonator.

It is further possible that two or more curved side walls of the same element of the active stack have different radii.

Specifically, it is possible that one or more curved side walls of an element of the active stack have a first radius while one or more other side walls of the same element of the acoustic stack have a second radius.

It is possible that two or more curved side walls of different elements of the active stack have different radii.

Specifically, it is possible that the radius of corresponding side walls of different elements of the active stack have a radius that is smaller when the corresponding element is arranged at a higher vertical position.

Specifically, it is possible that the overall area of the corresponding upper element—compared to a lower element—is smaller.

This simplifies manufacturing steps and helps improve the insulation between the bottom electrode and the top electrode.

It is possible that such a resonator is used as a resonator in an RF filter. Correspondingly, an RF filter can comprise one or more of the BAW resonators as described above.

Also, it is possible that such an RF filter can be used in a multiplexer. Correspondingly, a multiplexer can comprise one or more RF filters as described above.

The multiplexer can be a duplexer or a diplexer, a quadplexer or a multiplexer of a higher order.

Central technical aspects of the resonator and details of preferred embodiments are shown in the schematic accompanying figures.

In the figures:

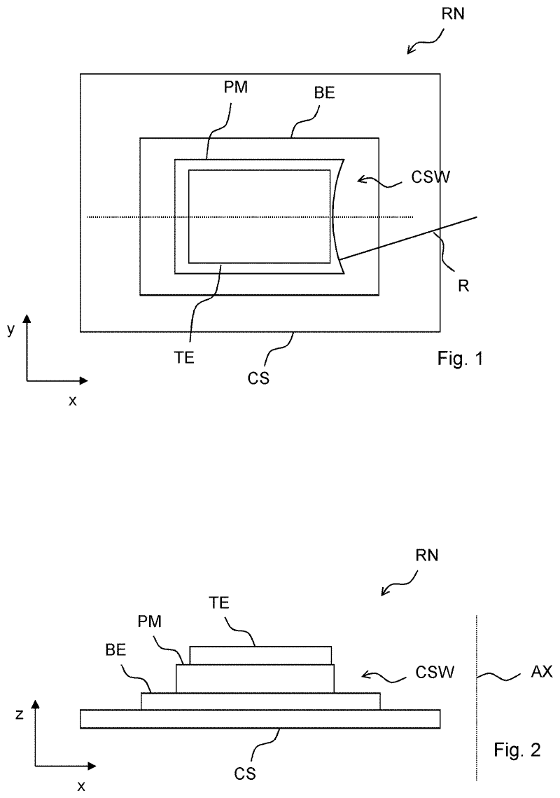

FIG. 1 shows a resonator RN with a curved side wall CSW in a top view,

FIG. 2 shows a cross-section of the resonator shown in FIG. 1;

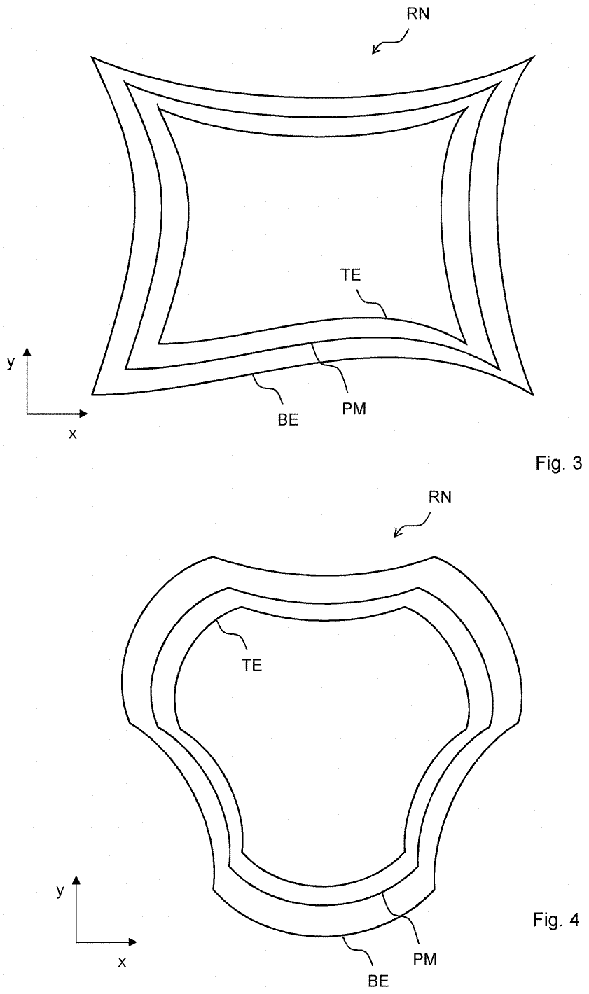

FIG. 3 shows a resonator where each element has four curved side walls;

FIG. 4 shows a resonator where each element of the active stack has six curved side walls;

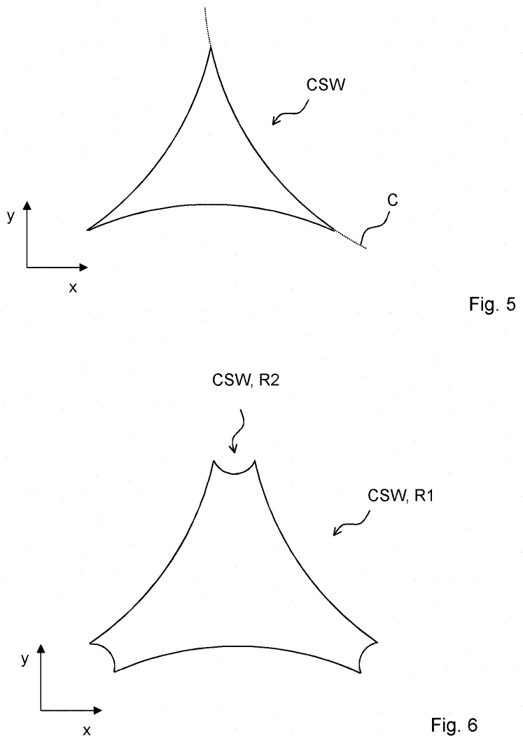

FIG. 5 shows a footprint of a resonator where a curved side wall establishes a segment of a circle;

FIG. 6 shows the possibility of different radii for an element of the active stack;

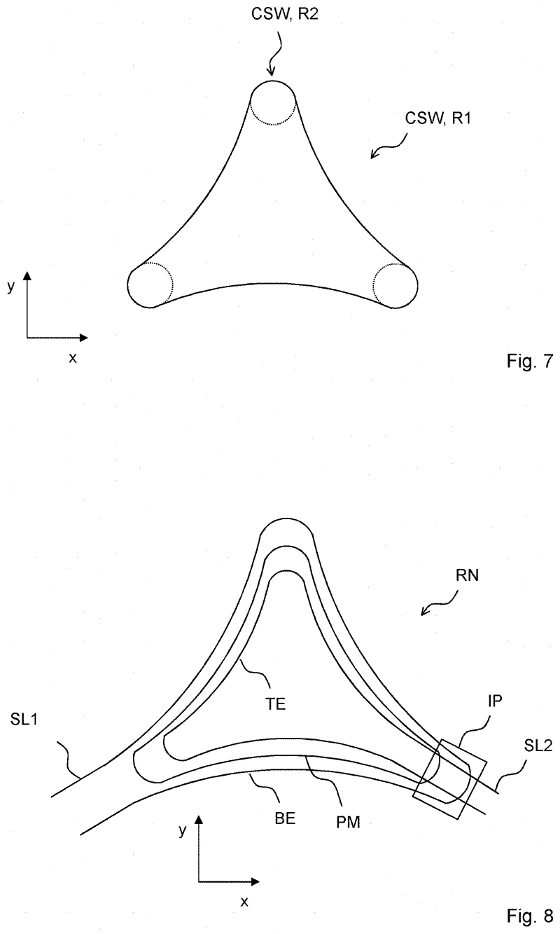

FIG. 7 shows the possibility of using convex and concave segments for the side walls;

FIG. 8 shows a resonator including signal lines to the bottom electrode and to the top electrode;

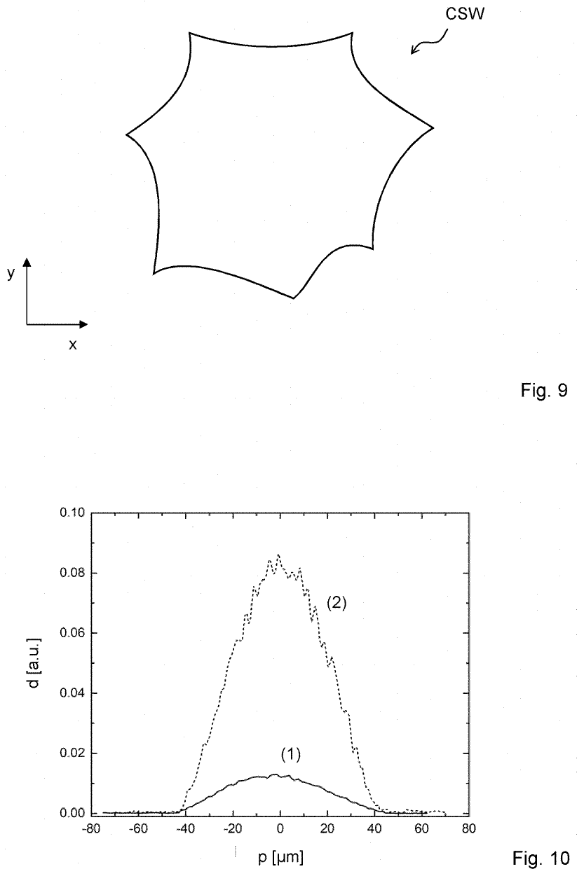

FIG. 9 shows a footprint of a resonator with seven curved side walls where each curved side wall is irregularly curved;

FIG. 10 shows a comparison of deflections between a resonator with curved side walls and a resonator with plane side walls;

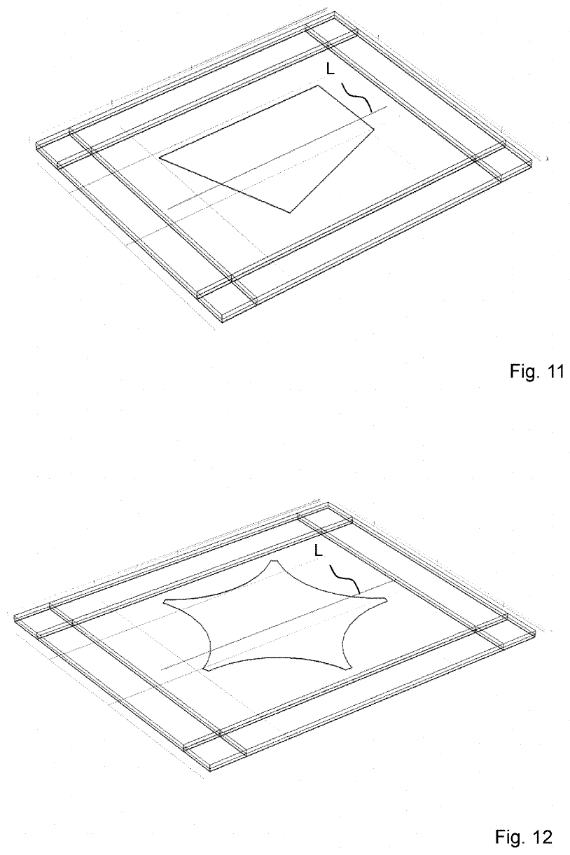

FIGS. 11 and 12 show the shape of the resonators to which FIG. 10 refers;

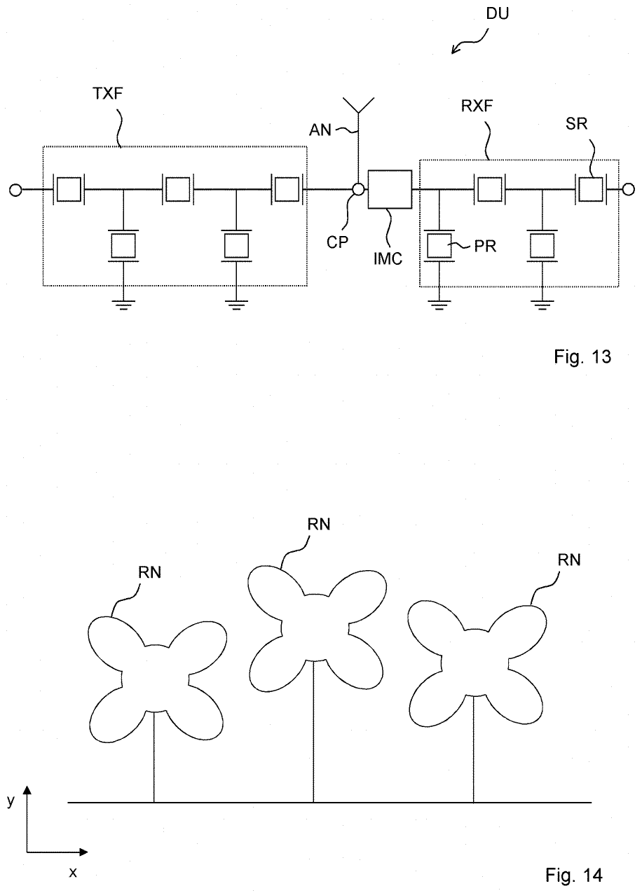

FIG. 13 illustrates a possible equivalent circuit diagram of a duplexer having filters with ladder-type like circuit topologies; and

FIG. 14 illustrates the spatial arrangement of different resonators in an area-saving pattern.

FIG. 1 shows a resonator RN with a piezoelectric material PM with a curved side wall CSW in a top view. The resonator has the bottom electrode BE arranged on a carrier substrate CS. The piezoelectric material PM is arranged on the bottom electrode BE. The top electrode TE is arranged on the piezoelectric material PM. The surface of the carrier substrate CS essentially extends along the xy plane. The electrodes and the piezoelectric material are stacked in the vertical direction orthogonal to the x and to the y direction. The curved side wall CSW of the piezoelectric material establishes a segment of a cylinder. The cylinder has its symmetry axis parallel to the z direction. Thus, each point of the curved side wall CSW has a distance equal to the radius R towards the cylinder symmetry axis AX.

Correspondingly, FIG. 2 shows a cross-section through the layer stack of the resonator RN shown in FIG. 1. Specifically, FIG. 2 shows the stack of the elements arranged one another in the vertical direction z. Specifically, the bottom element BE is arranged on the carrier substrate CS. The piezoelectric material PM is arranged on the bottom electrode BE. The top electrode TE is arranged on the piezoelectric material PM. AX denotes the symmetry axis of the cylinder that has the same distance towards each point of the curved side wall CSW.

FIG. 3 illustrates a possible shape for the bottom electrode BE, the piezoelectric material PM and the top electrode TE where three curved side walls for each element of the active stack has a concave shape where the fourth curved side wall has a convex segment and a concave segment.

FIG. 4 illustrates a geometry where three curved side walls of each element of the active stack have a convex shape where the other three curved side walls have a concave shape. Each of the curved side walls bases on circle segments. Thus, for each of the curved side walls there is a symmetry axis of a cylinder arranged in an equal distance for all points of the curved side walls. The symmetry axis of the cylinders for the convex curved side walls can lie within the area of the element. The corresponding symmetry lines of the concave portions can lie outside the base area of the resonator.

FIG. 5 illustrates a possible construction of a base area of a resonator such that the curved side walls establish segments of circles C. In contrast, FIG. 6 illustrates an embodiment where the corners/edges are replaced by concavely shaped curved side walls. The larger curved side walls correspond to a first radius R₁. The smaller curved side walls correspond to a second radius R₂ that is smaller than the firs radius R₁.

FIG. 7 illustrates a base area of a resonator where the larger curved side walls are concave and where the smaller curved side walls are convex.

FIG. 8 additionally shows signal lines electrically connecting the electrode of the resonator. Specifically, a first signal line SL₁ electrically connects the bottom electrode BE of the resonator. A second signal line SL₂ electrically connects the top electrode TE of the resonator RN. In order to prevent a short circuit between the bottom electrode BE and the top electrode TE a further insulating patch IP comprising or consisting of an insulating material is arranged between the second signal line and the bottom electrode BE.

FIG. 9 illustrates the possibility of having a base area with only irregularly curved side walls CSW.

FIG. 10 shows a simulation of the deflections d(p) of two resonators with different shapes with p being the lateral position. The deflection (curve 2) of a star shaped resonator as shown in FIG. 12 is substantially larger than the deflection (curve 1) of the resonator area than the state-of-the-art resonator with a tetragon as a base area with apodized sides shown in FIG. 11.

The substantially larger deflection of the resonator with curved side walls is a clear indication of a higher energy stored in the resonator. Thus, drain of energy, e.g. by lateral modes, is substantially reduced.

Figure ii shows a perspective view of the tetragon referred to with respect to FIG. 10. The line L crossing the resonator area indicates the cut position and the position p shown in FIG. 10.

Correspondingly, FIG. 12 shows a perspective view of the star shaped resonator referred to with respect to FIG. 10. The line L crossing the resonator area indicates the cut position and the position p shown in FIG. 10.

FIG. 13 shows the topology of a duplexer DU. The duplexer DU has a transmission filter TXF between a transmission port and a common port CP and a reception filter RXF between a reception filter and the common port CP. Further, an impedance matching circuit IMC can be arranged between the common port and the reception filter RXF. The transmission filter TXF and the reception filter RXF can have a ladder-type like circuit topology with series resonators SR electrically connected in series and with parallel resonators PR electrically connecting the signal line to a ground potential. The common port CP can be connected to antenna AN to emit transmission signals and to receive reception signals.

FIG. 14 shows resonators RN where a central portion has curved side walls corresponding to segments of a circle. Further curved side walls establish lobes extending from the center of the resonator. The resonators RN, e.g. parallel resonators PR that are electrically connected to a signal line can be arranged in such a pattern that lobes of one resonator are arranged in interstitial areas between lobes of a neighboring resonator.

Depending on the number of lobes, the resonators can be arranged in a quadratic or rectangular pattern when the number of lobes is four. For six lobes per resonator the resonators can be arranged in a hexagonal pattern on the carrier substrate.

The resonator, the filter and the multiplexer is not limited to technical features described above or shown in the figures. The resonator can comprise further elements such as additional layers within the layer stack, e.g. trimming layers, passivation layers, elements for shaping the preferred wave mode within the resonator structure, cavities or mirrors for confining acoustic energy.
AN: antenna
AX: symmetry axis
BE: bottom electrode
C: circle
CP: common port
CS: carrier substrate
CSW: curved side wall
d: deflection
DU: duplexer
IMC: impedance matching circuit
IP: insulating patch
L: line of positions p
p: lateral position
PM: piezoelectric material
PR: parallel resonator
R: radius
R₁, R₂: first, second radius
RN: resonator
RXF: reception filter
SL₁₁, SL₂: first, second signal line
SR: series resonator
TE: top electrode
TXF: transmission filter

1. A BAW resonator with reduced lateral modes, comprising an active stack including
a bottom electrode in a bottom electrode layer,
a top electrode in a top electrode layer,
a piezoelectric material in a piezoelectric layer between the bottom electrode layer and the top electrode layer,
wherein
at least one element selected from the active stack has a curved side wall.

2. The BAW resonator of claim 1, wherein two or all side walls of the active stack have a curved side wall.

3. The BAW resonator of claim 1, wherein the number of side walls of one or more element of the active stack is an odd number.

4. The BAW resonator of claim 1, wherein the one or more curved side walls are arranged on a sphere, on a cylinder or on a prism.

5. The BAW resonator of claim 1, wherein two or more curved side walls are arranged on spheres, on cylinders or prisms with an elliptical footprint with different radii.

6. The BAW resonator of claim 1, wherein two or more curved side walls of the same element of the active stack have different radii.

7. The BAW resonator of claim 1, wherein two or more curved side walls of different elements of the active stack have different radii.

8. The BAW resonator of claim 1, wherein the BAW resonator is part of an RF filter comprising one or more BAW resonators.

9. The BAW resonator of claim 8, wherein the RF filter is part of a multiplexer comprising one or more RF filters.
